(19) United States
(12) Patent Application Publication
(10) Pub. No.: US 2019/0007136 A1
(43) Pub. Date: Jan. 3, 2019

(54) Substrate, Display Panel and Display Apparatus

(71) Applicants: BOE TECHNOLOGY GROUP CO., LTD., Beijing (CN); BEIJING BOE MULTIMEDIA TECHNOLOGY CO., LTD., Beijing (CN)

(72) Inventors: Hongna YE, Beijing (CN); Jiuxia YANG, Beijing (CN)

(73) Assignees: BOE TECHNOLOGY GROUP CO., LTD., Beijing (CN); BEIJING BOE MULTIMEDIA TECHNOLOGY CO., LTD., Beijing (CN)

(21) Appl. No.: 15/748,245

(22) PCT Filed: Jul. 19, 2017
(86) PCT No.: PCT/CN2017/093488

§ 371 Date: Jan. 29, 2018

(30) Foreign Application Priority Data
Sep. 5, 2016 (CN) 201610802351.3

(51) Int. Cl. H04B 10/116; H01L 27/144; H01L 31/0216; H04B 10/67; G09G 3/3225; H04B 10/50

(52) U.S. Cl. CPC H04B 10/116; H01L 27/1446; H01L 31/02164; H04B 10/671; G09G 2300/0828; H04B 10/502; G09G 2370/18; G09G 2320/064; G09G 3/3225

(57) ABSTRACT

A substrate is disclosed. The substrate includes a base substrate, and a light-shielding member and a light sensing layer on the base substrate. The light sensing layer includes at least one light sensor unit for detecting a visible light signal, and converts the visible light signal detected by the at least one light sensor unit into an electrical signal corresponding to a light intensity of the visible light signal. The light-shielding member blocks light at one side from irradiating onto the light sensor unit. A display panel and a display apparatus are also disclosed.

### TECHNICAL FIELD

The present disclosure relates to the field of display technology, and particularly relates to a substrate, a display panel including the substrate and a display apparatus including the display panel.

### BACKGROUND

Light Fidelity (LiFi) is an optical wireless data transmission technology using a light source. A light emitting diode (LED) is controlled to flicker at a frequency of millions of times per second to transmit a digital signal of data “1” indicated by light emission or data “0” indicated by light non-emission. The frequency of the flickering is so high that a human eye cannot perceive the flickering. In addition, the transmitted digital signal can be detected by a light sensor, thereby forming a wireless communication system formed by a light emitting element such as an LED and a light sensor.

In the prior art, data sent by a LED serving as a transmitting terminal of wireless communication is typically received by a dedicated terminal device.

### SUMMARY

An object of the present disclosure is to provide a substrate that can receive date while being applied to a display panel, a display panel including the substrate, and a display apparatus including the display panel.

According to an aspect of the present disclosure, there is provided a substrate including a base substrate, and a light-shielding member and a light sensing layer on the base substrate. The light sensing layer includes at least one light sensor unit for detecting a visible light signal, and converts the visible light signal detected by the at least one light sensor unit into an electrical signal corresponding to a light intensity of the visible light signal. The light-shielding member blocks light at a side of the light-shielding member distal to the light sensing layer from irradiating onto the light sensor unit.

According to an embodiment of the present disclosure, the substrate may be divided into a plurality of pixel units, and the substrate includes a black matrix located at a boundary of each of the plurality of pixel units. The light-shielding member may be a part of the black matrix.

According to an embodiment of the present disclosure, an edge of the light sensor unit may be aligned with an edge of the light-shielding member that blocks light from irradiating onto the light sensor unit. Each light sensor unit corresponds to at least one pixel unit surrounded by the black matrix.

According to an embodiment of the present disclosure, the light sensing layer may include a plurality of light sensor units, and any two adjacent light sensor units are configured to be spaced apart from each other.

According to an embodiment of the present disclosure, the light sensing layer may be between the base substrate and the light-shielding member. Alternatively, the base substrate may be between the light sensing layer and the light-shielding member.

According to an embodiment of the present disclosure, the light sensor unit may include a photodiode.

According to another aspect of the present disclosure, there is provided a display panel including an array substrate and an opposite substrate. The opposite substrate may be the substrate according to the present disclosure, and the light sensing layer may face a light exiting side of the display panel.

According to another aspect of the present disclosure, there is provided a display apparatus including the display panel according to the present disclosure and a processing circuit. The processing circuit may be configured to receive the electrical signal converted by the light sensing layer and convert the received electrical signal into data information.

According to an embodiment of the present disclosure, the display apparatus may further include a backlight source including a light emitting element and provided on a light incident side of the display panel. The processing circuit may be further configured to control a switching frequency of the light emitting element of the backlight source such that the light emitting element transmits an optical signal carrying predetermined information.

According to an embodiment of the present disclosure, the processing circuit may include a first processing circuit. The first processing circuit includes a modulation circuit and a light emission control circuit electrically coupled to each other, and the light emission control circuit is electrically coupled to the light emitting element of the backlight source. The modulation circuit may be configured to convert data to be transmitted into a modulated signal, and transmit the modulated signal to the light emission control circuit. The light emission control circuit may be configured to receive the modulated signal, and control the switching frequency of the light emitting element according to the modulated signal.

According to an embodiment of the present disclosure, the processing circuit may include a second processing circuit. The second processing circuit includes an analog-to-digital conversion circuit and a demodulation circuit that are electrically coupled to each other. The analog-to-digital conversion circuit may be configured to convert the received electrical signal into a digital signal and transmit the digital signal to the demodulation circuit. The demodulation circuit may be configured to receive the digital signal and demodulate the digital signal to obtain the data information.

According to an embodiment of the present disclosure, the analog-to-digital conversion circuit may be configured to process the visible light signal detected by any one of the light sensor units included in the light sensing layer. Alternatively, the analog-to-digital conversion circuit may be configured to process the visible light signals detected by all of the light sensor units included in the light sensing layer.

According to the substrate of the present disclosure, by providing, on the substrate, a light sensing layer for detecting a visible light signal, the substrate can be used as a terminal device for receiving an optical signal.

### BRIEF DESCRIPTION OF THE DRAWINGS

The accompanying drawings, which are used for providing a further understanding of the present disclosure and constitute a part of the specification, are used for explaining the present disclosure together with the following specific implementations, but are not intended to limit the present disclosure. In the drawings:

FIG. 1 is a schematic structural diagram of a substrate according to an embodiment of the present disclosure;

FIG. 2 is a schematic diagram of a substrate divided into a plurality of pixel units according to an embodiment of the present disclosure;

FIG. 3 is a schematic structural diagram of a substrate according to another embodiment of the present disclosure;

FIG. 4 is a schematic structural diagram of a display panel according to an embodiment of the present disclosure;

FIG. 5 is a block diagram of a structure of a first processing circuit in a display apparatus according to an embodiment of the present disclosure;

FIG. 6 is a schematic diagram of transmitting data by a display apparatus according to an embodiment of the present disclosure;

FIG. 7 is a block diagram of a structure of a second processing circuit in a display apparatus according to an embodiment of the present disclosure;

FIG. 8 is a schematic diagram of receiving data by a display apparatus according to an embodiment of the present disclosure; and

FIGS. 9 and 10 are schematic structural diagrams of photodiodes that can be applied to a substrate according to an embodiment of the present disclosure.

### DETAILED DESCRIPTION

Specific implementations of the present disclosure will be described in detail below in conjunction with the accompanying drawings. It should be understood that, the specific implementations described herein are only used for describing and explaining the present disclosure, rather than limiting the present disclosure.

For ease of description, spatially relative terms, such as “beneath”, “below”, “under”, “above”, “on” and the like may be used herein to describe the relationship between one element or feature and another element(s) or feature(s) as illustrated in the figures. It should be understood that, the spatially relative terms are intended to encompass different orientations of the device in use or operation in addition to the orientation depicted in the figures. For example, if the device in the figures is turned over, an element described as “below” or “beneath” other elements or features will thus be oriented “above” the other elements or features. Thus, the term “below” may encompass both the “above” and “below”. The apparatus may be otherwise oriented (rotated by 90 degrees or at other orientations) and the spatially relative descriptors used herein may likewise be interpreted accordingly.

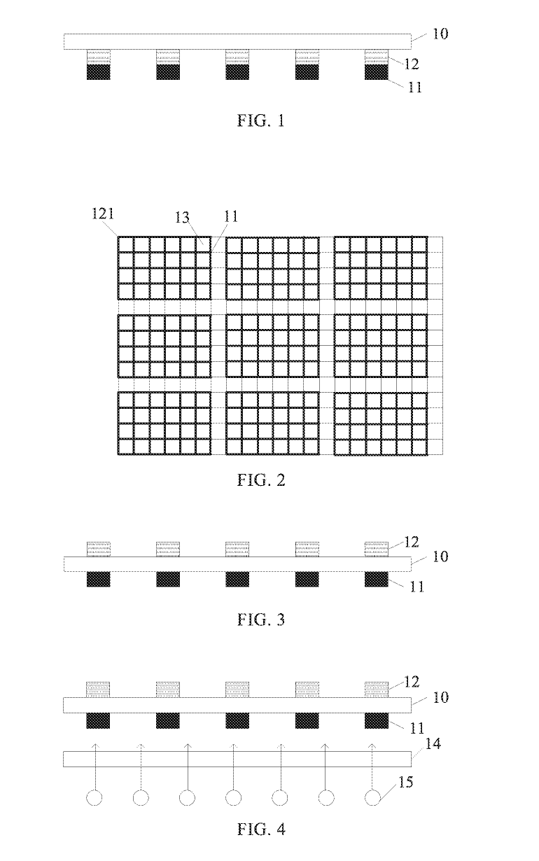

FIG. 1 is a schematic structural diagram of a substrate according to an embodiment of the present disclosure. FIG. 2 is a schematic diagram of a substrate divided into a plurality of pixel units according to an embodiment of the present disclosure.

Referring to FIGS. 1 and 2, a substrate according to an embodiment of the present disclosure includes a base substrate 10 and a light-shielding member 11 and a light sensing layer 12 that are provided on the base substrate 10. The light sensing layer 12 includes at least one light sensor unit 121 for detecting a visible light signal, and the light sensing layer 12 converts the visible light signal detected by the light sensor unit 121 into an electrical signal corresponding to a light intensity of the visible light signal. The light-shielding member 11 blocks light at a side of the light-shielding member 11 distal to the light sensing layer 12 from irradiating onto the light sensor unit 121.

The substrate according to the embodiment of the present disclosure can receive a visible light signal incident from one side of the base substrate 10 through the light sensing layer 12 provided on the base substrate 10, and the light-shielding member 11 can block light from the other side of the base substrate 10 from irradiating onto the light sensing layer 12. The light sensor unit 121 of the light sensing layer 12 can detect the received visible light signal and convert the detected visible light signal into an electrical signal.

When the substrate according to the present disclosure is applied to a display panel, the substrate can achieve a function of receiving data. In addition, when the display panel having the substrate according to the present disclosure is applied to a display apparatus, the light-shielding member 11 can block light from a backlight source from irradiating on the light sensing layer 12. In this case, the light-shielding member 11 may form a light shielding area.

According to an embodiment of the present disclosure, as shown in FIG. 2, the substrate is divided into a plurality of pixel units 13, and the substrate includes a black matrix at a boundary of each of the pixel units 13. The light-shielding member 11 may be a part of the black matrix.

In order to prevent the light sensor unit 121 of the light sensing layer 12 on the base substrate 10 from receiving a visible light signal emitted by the display apparatus itself, the light sensor unit 121 may be disposed within the light-shielding area formed by the light-shielding member 11 completely. According to an embodiment of the present disclosure, an edge of the light sensor unit 121 may be aligned with an edge of the corresponding light-shielding member 11. In addition, each light sensor unit 121 may correspond to at least one pixel unit 13.

According to an embodiment of the present disclosure, as shown in FIG. 2, each of the light sensor units 121 corresponds to a plurality of pixel units 13, so as to increase a light sensing area of each light sensor unit 121 to avoid or alleviate problem of communication interruption due to small light sensing area of the light sensor.

As shown in FIG. 2, each of the light sensor units 121 corresponds to a plurality of pixel units 13, and is located in a light-shielding area formed by the black matrix. Each small cell in FIG. 2 represents one pixel unit 13, a blank area in each small cell is a display area, and a grid formed by black lines represents the black matrix. It could be seen from FIG. 2 that each light sensor unit 121 is formed in a grid shape.

According to an embodiment of the present disclosure, the light sensor units 121 included in the light sensing layer 12 are insulated from each other, that is, any two adjacent light sensor units 121 are provided to be spaced apart from each other.

It should be understood that the light sensor units 121 included in the light sensing layer 12 may operate independently or in cooperation. The light sensor units 121 may independently detect a same visible light signal and respectively convert the detected visible light signal to obtain a same electrical signal. In addition, in a case where the visible light signal is so weak that each individual light sensor unit 121 cannot detect a complete visible light signal (or, light intensity of the visible light signal detected by each individual light sensor unit 121 is different), the light sensor units 121 may operate cooperatively, and convert respective detected visible light signals of different intensities into corresponding electrical signals, so as to obtain relatively complete data information. The cooperation of a plurality of light sensor units improves detection sensitivity of the display apparatus using the substrate and facilitates acquisition of complete data information.

FIG. 3 is a schematic structural diagram of a substrate according to another embodiment of the present disclosure.

In the embodiment shown in FIG. 1, the light sensing layer 12 is located between the base substrate 10 and the light-shielding member 11. Different from the embodiment shown in FIG. 1, as shown in FIG. 3, the base substrate 10 is located between the light sensing layer 12 and the light-shielding member 11.

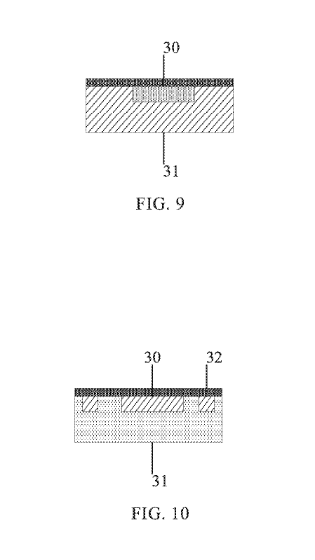

According to an embodiment of the present disclosure, the light sensor unit 121 may include a photodiode. FIG. 9 and FIG. 10 show schematic structural diagrams of photodiodes that can be applied to a substrate according to an embodiment of the present disclosure.

The photodiode may include a 2CU photodiode (as shown in FIG. 9) and a 2DU photodiode (as shown in FIG. 10). Referring to FIGS. 9 and 10, the 2CU photodiode and the 2DU photodiode each may include a cathode 30 and an anode 31. Compared with the 2CU photodiode, the 2DU photodiode further includes an annular electrode 32 (an electrode led out from an annular diffusion layer) for reducing dark current of the photodiode. The Type of the photodiode may be chosen as actually required. For example, the 2DU photodiode may be selected when lower power consumption is required.

According to an embodiment of the present disclosure, a color filter layer may be provided on the substrate according to the present disclosure. In this case, the substrate may be formed as a color filter substrate.

FIG. 4 is a schematic structural diagram of a display panel according to an embodiment of the present disclosure.

As shown in FIG. 4, the display panel according to the embodiment of the present disclosure may include an array substrate 14 and an opposite substrate. The opposite substrate may be the substrate according to any one of the foregoing embodiments of the present disclosure, and the light-shielding member 11 of the opposite substrate is arranged between the array substrate 14 and the light sensing layer 12. Therefore, the opposite substrate may be provided on the light-exiting side of the array substrate 14, and the light-shielding member 11 of the opposite substrate may be configured to face the array substrate 14.

FIG. 4 shows a case where the substrate shown in FIG. 3 is adopted, but the substrate shown in FIG. 1 may also be used.

The display panel according to the present disclosure can be applied to various display apparatuses. The display apparatus may further include a processing circuit configured to receive the electrical signal converted by the light sensing layer and convert the received electrical signal into data information.

With the light sensing layer, the display apparatus according to the present disclosure can be used not only for image display but also for LIFI communication.

After obtaining the data information, the display apparatus may display the obtained data information directly or store the data information.

According to an embodiment of the present disclosure, the display apparatus may further include a backlight source including a light emitting element (the light emitting element 15 in FIG. 4) and provided on a light incident side of the display panel. The processing circuit of the display apparatus may be configured to control a switching frequency of the light emitting element 15 to cause the light emitting element 15 to transmit an optical signal carrying predetermined information, thereby realizing optical communication.

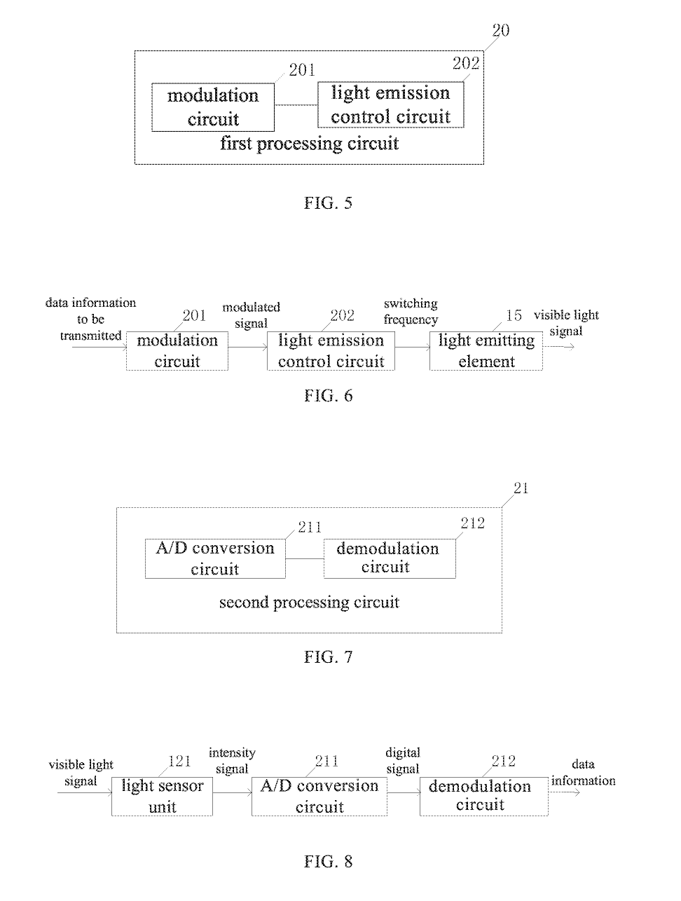

FIG. 5 is a block diagram of a structure of a first processing circuit in a display apparatus according to an embodiment of the present disclosure. FIG. 6 is a schematic diagram of transmitting data by the display apparatus according to an embodiment of the present disclosure.

Referring to FIGS. 5 and 6, the processing circuit of the display apparatus according to the present disclosure may include a first processing circuit, which includes a modulation circuit 201 and a light emission control circuit 202 electrically coupled to each other, and the light emission control circuit 202 is electrically coupled to the light emitting element 15. The modulation circuit 201 converts data information to be transmitted into a modulated signal, and transmits the modulated signal to the light emission control circuit 202. The light emission control circuit receives the modulated signal and controls the switching frequency of the light emitting element 15 according to the modulated signal. According to an embodiment of the present disclosure, the light emitting element 15 may be a bar-shaped light source or a point light source.

FIG. 7 is a block diagram of a structure of a second processing circuit in a display apparatus according to an embodiment of the present disclosure. FIG. 8 is a schematic diagram of receiving data by the display apparatus according to an embodiment of the present disclosure.

Referring to FIGS. 7 and 8, the processing circuit of the display apparatus according to the present disclosure may include a second processing circuit, which includes an analog-to-digital conversion circuit 211 and a demodulation circuit 212 electrically coupled to each other. The analog-to-digital conversion circuit 211 may convert the electrical signal received by the light sensor unit 121 into a digital signal, and transmit the digital signal to the demodulation circuit 212. The demodulation circuit 212 may receive the digital signal and demodulate the digital signal to obtain data information.

According to an embodiment of the present disclosure, the analog-to-digital conversion circuit 211 may process the visible light signal detected by any one of the light sensor units 121 (i.e., independent operation mode of the light sensor units 121). Alternatively, the analog-to-digital conversion module 211 may process the visible light signals detected by all of the light sensor units 121 (i.e., cooperative operation mode of the light sensor units 121).

In the independent operation mode, the analog signals indicating light intensity detected by the individual light sensor units 121 are A1, A2, . . . , An, respectively, and are subjected to analog-to-digital conversion to obtain corresponding digital modulated signals D1, D2, . . . , Dn, respectively, and the digital modulated signals are demodulated to obtain data S1, S2, . . . , Sn. In a case where one of the light sensor units is blocked or receives so weak light that the light sensor unit cannot obtain the demodulated data, in the independent operation mode, data obtained by another light sensor unit that is not blocked may be chosen, so as to ensure reception of data in a condition that part of area is blocked. In cooperative operation mode, the analog signals indicating the light intensity detected by the individual light sensor units 121 are summed, that is, A=A1+A2+. . . +An, and the sum A is subjected to analog to digital conversion to obtain digital modulated signal D, and data S is finally obtained, thereby improving detection sensitivity of the display apparatus serving as a receiving terminal.

It could be understood that the above embodiments are merely exemplary embodiments adopted for describing the principle of the present disclosure, but the present disclosure is not limited thereto. Various variations and improvements may be made by those of ordinary skill in the art without departing from the spirit and essence of the present disclosure, and these variations and improvements shall also be regarded as falling into the protection scope of the present disclosure.

1-14. (canceled)

15. A substrate, comprising:
a base substrate,
a light-shielding member on the base substrate, and
a light sensing layer on the base substrate,
wherein the light sensing layer comprises at least one light sensor unit configured to detect a visible light signal, and the light sensing layer is configured to convert the visible light signal detected by the at least one light sensor unit into an electrical signal corresponding to a light intensity of the visible light signal, and
the light-shielding member is configured to block light at a side of the light-shielding member distal to the light sensing layer from irradiating onto the light sensor unit.

16. The substrate of claim 15, wherein the substrate is divided into a plurality of pixel units, and the substrate comprises a black matrix at a boundary of each of the plurality of pixel units, and
the light-shielding member is a part of the black matrix.

17. The substrate of claim16, wherein an edge of the light sensor unit is aligned with an edge of the light-shielding member that blocks light from irradiating onto the light sensor unit, and each light sensor unit corresponds to at least one pixel unit surrounded by the black matrix.

18. The substrate of claim 15, wherein the light sensing layer comprises a plurality of light sensor units, and any two adjacent light sensor units are configured to be spaced apart from each other.

19. The substrate of claim 15, wherein the light sensing layer is between the base substrate and the light-shielding member.

20. The substrate of claim 15, wherein the base substrate is between the light sensing layer and the light-shielding member.

21. The substrate of claim 15, wherein the light sensor unit comprises a photodiode.

22. A display panel, comprising an array substrate and an opposite substrate, wherein the opposite substrate comprises:
a base substrate,
a light-shielding member on the base substrate, and
a light sensing layer on the base substrate,
wherein the light sensing layer comprises at least one light sensor unit configured to detect a visible light signal, and the light sensing layer is configured to convert the visible light signal detected by the at least one light sensor unit into an electrical signal corresponding to a light intensity of the visible light signal, and
the light-shielding member is configured to block light at a side of the light-shielding member distal to the light sensing layer from irradiating onto the light sensor unit, and the light-shielding member is arranged between the array substrate and the light-shielding member.

23. A display apparatus, comprising the display panel of claim 22 and a processing circuit,
wherein the processing circuit is configured to receive the electrical signal converted by the light sensing layer and convert the received electrical signal into data information.

24. The display apparatus of claim 23, further comprising a backlight source, which comprises a light emitting element and is disposed on a light incident side of the display panel,
wherein the processing circuit is further configured to control a switching frequency of the light emitting element of the backlight source such that the light emitting element transmits an optical signal carrying predetermined information.

25. The display apparatus of claim 24, wherein the processing circuit comprises a first processing circuit, the first processing circuit comprises a modulation circuit and a light emission control circuit electrically coupled to each other, and the light emission control circuit is electrically coupled to the light emitting element of the backlight source,
wherein the modulation circuit is configured to convert data to be transmitted into a modulated signal, and transmit the modulated signal to the light emission control circuit, and
the light emission control circuit is configured to receive the modulated signal, and control the switching frequency of the light emitting element according to the modulated signal.

26. The display apparatus of claim 23, wherein the processing circuit comprises a second processing circuit, and the second processing circuit comprises an analog-to-digital conversion circuit and a demodulation circuit electrically coupled to each other,
wherein the analog-to-digital conversion circuit is configured to convert the received electrical signal into a digital signal and transmit the digital signal to the demodulation circuit, and
the demodulation circuit is configured to receive the digital signal and demodulate the digital signal to obtain the data information.

27. The display apparatus of claim 26, wherein the analog-to-digital conversion circuit is configured to process the visible light signal detected by any one of the light sensor units included in the light sensing layer.

28. The display apparatus of claim 26, wherein the analog-to-digital conversion circuit is configured to process the visible light signals detected by all of the light sensor units included in the light sensing layer.

29. The display apparatus of claim 24, wherein the processing circuit comprises a second processing circuit, and the second processing circuit comprises an analog-to-digital conversion circuit and a demodulation circuit electrically coupled to each other,
wherein the analog-to-digital conversion circuit is configured to convert the received electrical signal into a digital signal and transmit the digital signal to the demodulation circuit, and
the demodulation circuit is configured to receive the digital signal and demodulate the digital signal to obtain the data information.

30. The display apparatus of claim 29, wherein the analog-to-digital conversion circuit is configured to process the visible light signal detected by any one of the light sensor units included in the light sensing layer.

31. The display apparatus of claim 29, wherein the analog-to-digital conversion circuit is configured to process the visible light signals detected by all of the light sensor units included in the light sensing layer.

32. The display apparatus of claim 25, wherein the processing circuit comprises a second processing circuit, and the second processing circuit comprises an analog-to-digital conversion circuit and a demodulation circuit electrically coupled to each other,
wherein the analog-to-digital conversion circuit is configured to convert the received electrical signal into a digital signal and transmit the digital signal to the demodulation circuit, and
the demodulation circuit is configured to receive the digital signal and demodulate the digital signal to obtain the data information.

33. The display apparatus of claim 32, wherein the analog-to-digital conversion circuit is configured to process the visible light signal detected by any one of the light sensor units included in the light sensing layer.

34. The display apparatus of claim 32, wherein the analog-to-digital conversion circuit is configured to process the visible light signals detected by all of the light sensor units included in the light sensing layer.
